(19) United States
(12) Patent Application Publication
(10) Pub. No.: US 2026/0082765 A1
(43) Pub. Date: Mar. 19, 2026

(54) LIGHT-EMITTING ELEMENT, LIGHT-EMITTING DEVICE, AND PRODUCTION METHOD FOR SAID LIGHT-EMITTING DEVICE

(71) Applicant: Sharp Display Technology Corporation, Kameyama City, Mie (JP)

(72) Inventors: Kota ADACHI, Sakai City, Osaka (JP); YASUSHI ASAOKA, Sakai City, Osaka (JP)

(21) Appl. No.: 19/109,229

(22) PCT Filed: Sep. 8, 2022
(86) PCT No.: PCT/JP2022/033670

§ 371 Date: Mar. 6, 2025

(51) Int. Cl. H10K 50/16; H10K 50/15; H10K 85/10

(52) U.S. Cl. CPC H10K 50/16; H10K 50/15; H10K 85/10

(57) ABSTRACT

A light-emitting element includes: a first electrode; a second electrode; a light-emitting layer provided between the first electrode and the second electrode; and a charge transport layer provided between the first electrode and the light-emitting layer, wherein the charge transport layer includes a metal oxide nanoparticle, an organic ligand is chemically bonded to the metal oxide nanoparticle via a surface hydroxyl group of the metal oxide nanoparticle, a bond enthalpy at 298 K between bonding atoms at a bonding site between the organic ligand and the surface hydroxyl group is 326.7 kJ/mol or more, and the organic ligand includes a phosphonic acid.

### TECHNICAL FIELD

The disclosure relates to a light-emitting element and a light-emitting device, and a method for manufacturing the light-emitting device.

### BACKGROUND ART

Light-emitting elements using metal oxide nanoparticles as charge transport materials have been proposed in recent years. The metal oxide nanoparticles have high resistance to foreign matter such as moisture and heat and are excellent in stability, as compared with organic materials. On the other hand, the metal oxide nanoparticles have a low charge transport property, as compared with the organic materials having a charge transporting property. Thus, to improve charge transport efficiency, inorganic nanoparticles having a small particle size have been developed. The smaller the particle size of the metal oxide nanoparticles is, the more the charge injection property into a light-emitting material is improved.

However, when the particle size of the metal oxide nanoparticles is decreased, the dispersibility of the metal oxide nanoparticles into a solvent is decreased and agglomeration is more likely to occur. Due to this, attempts have been made to coordinate organic ligands to surfaces of metal oxide nanoparticles to improve the dispersibility of the metal oxide nanoparticles.

For example, PTL 1 discloses a quantum dot light-emitting diode (QLED) including a cathode, an anode, a light-emitting layer disposed between the cathode and the anode, and a hole transport layer disposed between the anode and the light-emitting layer, in which a hole transport material includes a polyamidoamine (PAMAM) dendrimer and metal oxide nanoparticles bonded to amino groups on the PAMAM dendrimer. When the organic ligands are coordinated to the surfaces of the metal oxide nanoparticles as described above, the dispersibility of the metal oxide nanoparticles can be improved.

### CITATION LIST

### Patent Literature

PTL 1: WO 2020/108073 Pamphlet

### SUMMARY

### Technical Problem

However, in a self-luminous light-emitting element such as a QLED or an organic light-emitting diode (OLED), light emission is controlled by ON or OFF of a current flowing through the element or the amount of the current.

According to the study of the present inventor, when such a self-luminous light-emitting element is repeatedly driven, electrical characteristics of the element, in particular, a flowing current with respect to a voltage changes.

In particular, monoethanolamine or an organic ligand such as the PAMAM dendrimer used in PTL 1 is bonded to a metal oxide nanoparticle with an amino group. According to the study of the present inventor, the bond between an amino group and a metal oxide nanoparticle has a low bond enthalpy, and the organic ligand is easily detached by energization. Accordingly, electrical characteristics of an element are likely to change due to continuous driving of the element.

An aspect of the disclosure is made in view of the above problems, and is directed to providing a light-emitting element, a light-emitting device, and a method for manufacturing the light-emitting device that can suppress detachment of an organic ligand on a surface of a metal oxide nanoparticle in a charge transport layer due to energization and suppress a change in electrical characteristics due to continuous driving.

### Solution to Problem

To solve the above problems, a light-emitting element according to an aspect of the disclosure includes a first electrode, a second electrode, a light-emitting layer disposed between the first electrode and the second electrode, and a charge transport layer disposed between the first electrode and the light-emitting layer, in which the charge transport layer includes a metal oxide nanoparticle, an organic ligand is chemically bonded to the metal oxide nanoparticle via a surface hydroxyl group of the metal oxide nanoparticle, and a bond enthalpy at 298 K between bonding atoms at a bonding site between the organic ligand and the surface hydroxyl group is 326.7 kJ/mol or more.

To solve the problem described above, a light-emitting device according to an aspect of the disclosure includes at least one of the light-emitting elements according to an aspect of the disclosure.

To solve the above problems, a method for manufacturing a light-emitting device according to an aspect of the disclosure is a method for manufacturing a light-emitting device including a first light-emitting element provided with a first light-emitting layer and a first charge transport layer provided on the first light-emitting layer, the method including: performing first photoresist layer formation of forming a first photoresist layer in a region other than a region in which the first light-emitting layer is to be formed; performing first light-emitting layer formation of forming the first light-emitting layer on the first photoresist layer; performing first charge transport layer formation of forming the first charge transport layer on the first light-emitting layer; and performing first light-emitting layer and first charge transport layer patterning of patterning the first light-emitting layer and the first charge transport layer by removing the first photoresist layer to lift off the first light-emitting layer and the first charge transport layer on the first photoresist layer, in which in the first charge transport layer formation, the first charge transport layer is formed by applying a first charge transport layer material dispersion including a first metal oxide nanoparticle, a first organic ligand chemically bonded to the first metal oxide nanoparticle via a surface hydroxyl group of the first metal oxide nanoparticle and including fluorine at a terminal group, and a solvent, and having a bond enthalpy of 326.7 kJ/mol or more at 298 K between bonding atoms at a bonding site between the first organic ligand and the surface hydroxyl group, and removing the solvent.

### Advantageous Effects of Disclosure

According to an aspect of the disclosure, it is possible to provide a light-emitting element, a light-emitting device, and a method for manufacturing the light-emitting device that can suppress detachment of an organic ligand on a surface of a metal oxide nanoparticle in a charge transport layer due to energization and suppress a change in electrical characteristics due to continuous driving.

### BRIEF DESCRIPTION OF DRAWINGS

FIG. 1 is a cross-sectional view illustrating an example of a schematic configuration of a light-emitting element according to a first embodiment.

FIG. 2 is a diagram illustrating bonding between a phosphonic acid, a carboxylic acid, a silane, an isocyanic acid, and monoethanolamine and surface hydroxyl groups of metal oxide nanoparticles.

FIG. 3 is a diagram showing bond enthalpies of single bonds between bonding atoms at 298 K.

FIG. 4 is a graph showing a relationship between a ratio of a current density in the third energization to a current density in the first energization and a drive voltage when monoethanolamine and FOPA are used as an organic ligand.

FIG. 5 is a graph showing a relationship between a current density ratio and a drive voltage during first driving of a light-emitting element in a case where a phosphonic acid having 6 carbon atoms in a main chain is used as an organic ligand and in a case where monoethanolamine having 2 carbon atoms in a main chain is used as an organic ligand in an electron transport layer.

FIG. 6 is a graph showing a relationship between a current density and external quantum efficiency of each light-emitting element during the first driving of the light-emitting element in the case where phosphonic acid having 6 carbon atoms in the main chain is used as the organic ligand and the case where monoethanolamine having 2 carbon atoms in the main chain is used as the organic ligand in the electron transport layer.

FIG. 7 is a cross-sectional view illustrating an example of a schematic configuration of a light-emitting element according to a first modified example of the first embodiment.

FIG. 8 is a cross-sectional view illustrating an example of a schematic configuration of main portions of a light-emitting device according to a second embodiment.

FIG. 9 is a flowchart showing an example of a method for manufacturing the light-emitting device according to the second embodiment.

FIG. 10 is a flowchart showing an example of a step of forming a light-emitting element layer illustrated in FIG. 3.

FIG. 11 is a cross-sectional view illustrating an example of a part of the step shown in FIG. 10.

FIG. 12 is a cross-sectional view illustrating an example of another part of the step shown in FIG. 10.

FIG. 13 is a cross-sectional view illustrating an example of still another part of the step shown in FIG. 10.

### DESCRIPTION OF EMBODIMENTS

### First Embodiment

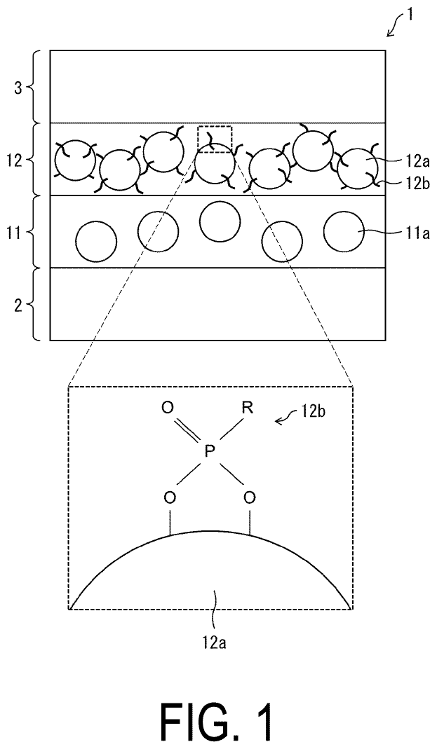

An embodiment of the disclosure will be described as follows with reference to FIG. 1 to FIG. 7. Note that, in the following, description of “from A to B” for two numbers A and B means “being equal to or greater than A and equal to or less than B”, unless otherwise specified. Further, in the following, a layer formed in a process prior to that of a layer being compared is referred to as a “lower layer,” and a layer formed in a process after that of a layer being compared is referred to as an “upper layer”.

A light-emitting element according to the present embodiment includes a first electrode, a second electrode, and function layers provided between the first electrode and the second electrode. In the disclosure, layers between the first electrode and the second electrode are referred to as function layers. The function layers include at least a light-emitting layer provided between the first electrode and the second electrode, and a charge transport layer provided between the first electrode and the light-emitting layer.

One of the first electrode and the second electrode is an anode, and the other is a cathode. Any of the first electrode and the second electrode may be an upper layer electrode. The light-emitting element according to the present embodiment may have a conventional structure in which the anode is a lower layer electrode and the cathode is an upper layer electrode, or may have an inverted structure in which the cathode is a lower layer electrode and the anode is an upper layer electrode.

In the following description, a case where the charge transport layer is an electron transport layer will be described as an example. Hereinafter, the light-emitting layer may be referred to as “EML”, the charge transport layer may be referred to as “CTL”, and the electron transport layer may be referred to as “ETL”.

FIG. 1 is a cross-sectional view illustrating an example of a schematic configuration of a light-emitting element 1 according to the present embodiment.

As an example, the light-emitting element 1 illustrated in FIG. 1 has a conventional structure in which an anode 2 is a lower layer electrode and a cathode 3 is an upper layer electrode, and has a configuration in which the anode 2, an EML 11, an ETL 12, and the cathode 3 are provided in this order from the lower layer side (e.g., a support body side not illustrated such as a substrate).

The anode 2 is an electrode that supplies positive holes to the EML 11 when a voltage is applied thereto. The cathode 3 is an electrode that supplies electrons to the EML 11 when a voltage is applied thereto. The anode 2 and the cathode 3 each contain a conductive material, and are connected to a power supply (not illustrated), whereby a voltage is applied therebetween.

At least one of the anode 2 and the cathode 3 is a light-transmissive electrode through which visible light passes. The light-transmissive electrode is formed of a light-transmissive material such as indium tin oxide (ITO), indium zinc oxide (IZO), silver nanowire (AgNW), a thin film of magnesium-silver (MgAg) alloy, or a thin film of silver (Ag), for example.

Any one of the anode 2 and the cathode 3 may be a so-called reflective electrode having light reflectivity. The reflective electrode may be formed of a light-reflective material, for example, a metal such as Ag or aluminum (Al), or an alloy containing these metals, or may be formed by layering a light-transmissive material and a light-reflective material.

In a case where the light-emitting element 1 is a top-emission type display element that emits light from the upper layer electrode side (the cathode 3 side in the example illustrated in FIG. 1), a light-transmissive electrode is used as the upper layer electrode, and a reflective electrode is used as the lower layer electrode. On the other hand, in a case where the light-emitting element 1 is a bottom-emission type display element that emits light from the lower layer electrode side (the anode 2 side in the example illustrated in FIG. 1), a light-transmissive electrode is used as the lower layer electrode, and a reflective electrode is used as the upper layer electrode.

The EML 11 is a layer that includes a light-emitting material and emits light by recombination of positive holes transported from the anode 2 and electrons transported from the cathode 3. The light-emitting element 1 is a quantum dot light-emitting diode (QLED), and the EML 11 contains nano-sized quantum dots (hereinafter, referred to as “QDs”) 11a corresponding to a light emission color as a light-emitting material.

The QDs 11a are dots composed of nanoparticles with a maximum width of 100 nm or less. QDs generally have a composition derived from a semiconductor material, and thus may also be called semiconductor nanoparticles. Furthermore, since QDs have a specific crystal structure, for example, they may also be called nanocrystals.

The shape of each of the QDs 11a is not particularly limited as long as it is within a range satisfying the maximum width, and the shape thereof is not limited to a spherical three-dimensional shape (circular cross-sectional shape). The shape may be, for example, a polygonal cross-sectional shape, a rod-like three-dimensional shape, a branch-like three-dimensional shape, or a three-dimensional shape having unevenness on the surface thereof, or a combination thereof.

The QDs 11a may each be of a core type, or a core-shell type or a core-multishell type including a core and a shell. In a case where the QD 11a includes a shell, it is sufficient that a core is located in the center and the shell is provided on the surface of the core. Although it is desirable for the shell to cover the entire core, the shell need not necessarily completely cover the core. Further, the QDs 11a may each be of a two-component core type, a three-component core type, or a four-component core type. Note that the QDs 11a may include doped nanoparticles, or may have a compositionally graded structure.

The core may be formed of, for example, Si, Ge, CdSe, CdS, CdTe, InP, GaP, InN, ZnSe, ZnS, ZnTe, CdSeTe, GaInP, ZnSeTe, or the like. The shell may be formed of, for example, CdS, ZnS, CdSSe, CdTeSe, CdSTe, ZnSSe, ZnSTe, ZnTeSe, AIP, or the like. Note that the QDs 11a may each have a ligand on its surface. The ligand is not particularly limited, and may be an organic ligand or an inorganic ligand, and various known ligands may be used.

The QDs 11a can have light emission wavelengths changed variously depending on particle sizes, compositions thereof, and the like. The QDs 11a are QDs that emit visible light, and can realize, for example, red light, green light, or blue light by appropriately adjusting the particle size and composition of the QDs 11a.

The ETL 12 is a CTL including an electron transporting material and having an electron transporting function of increasing electron transporting efficiency to the EML 11.

The ETL 12 illustrated in FIG. 1 contains metal oxide nanoparticles 12a as the electron transporting material. In general, the surface of a metal oxide nanoparticle is terminated with a hydroxyl group (—OH). In other words, the surface of a metal oxide nanoparticle is covered with hydroxyl groups. The ETL 12 has a configuration in which an organic ligand 12b is chemically bonded to each of the metal oxide nanoparticles 12a via a hydroxyl group (surface hydroxyl group) present on the surface of the metal oxide nanoparticle 12a. Thus, the ETL 12 illustrated in FIG. 1 includes the metal oxide nanoparticles 12a and the organic ligands 12b. Note that in the present embodiment, not only a molecule or an ion bonded to the surface of each of the metal oxide nanoparticles 12a but also a molecule or an ion that can be bonded but is not bonded is referred to as a “ligand”.

Examples of the metal oxide nanoparticles 12a include ZnO nanoparticles and MgZnO nanoparticles. These metal oxide nanoparticles have an excellent electron transporting property.

As the organic ligand 12b, an organic ligand having a bond enthalpy at 298 K between bonding atoms at a bonding site between the organic ligand 12b and the surface hydroxyl group of 326.7 kJ/mol or more is used.

Examples of such an organic ligand 12b include a phosphonic acid, a carboxylic acid, a silane, and an isocyanic acid. A single type of these organic ligands 12b may be used alone, or two or more types thereof may be mixed and used, as appropriate. Note that as will be understood from the description below, in the disclosure, a “phosphonic acid”, a “carboxylic acid”, a “silane”, and an “isocyanic acid” indicate “phosphonic acids”, “carboxylic acids”, “silanes”, and “isocyanic acids”, respectively.

FIG. 1 illustrates a case where the organic ligand 12b is a phosphonic acid as an example. However, the present embodiment is not limited thereto, and the organic ligand 12b may be at least one selected from the group consisting of a carboxylic acid, a silane, and an isocyanic acid. Note that in the disclosure, a silane represents a group of silicon compounds including chlorosilane, alkoxysilane, and silazane, and suitably represents monoalkoxysilane, dialkoxysilane, or trialkoxysilane represented by R¹R²R²Si—OX.

These phosphonic acid, carboxylic acid, silane, and isocyanic acid are covalently bonded to the metal oxide nanoparticles 12a via surface hydroxyl groups of the metal oxide nanoparticles 12a, and have higher interatomic bond energy than, for example, that of bonding between monoethanolamine and surface hydroxyl groups of the metal oxide nanoparticles 12a using amino groups.

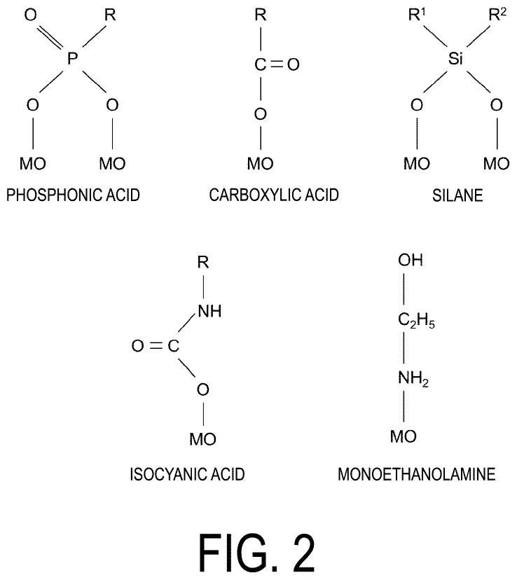

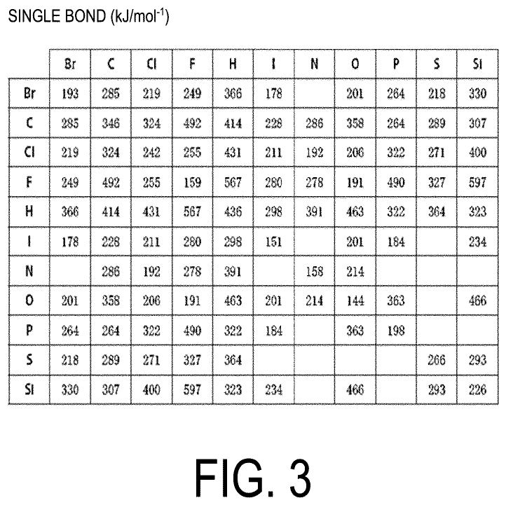

FIG. 2 illustrates bonds between these phosphonic acid, carboxylic acid, silane, and isocyanic acid and surface hydroxyl groups of the metal oxide nanoparticles 12a, together with a bond between monoethanolamine and a surface hydroxyl group of the metal oxide nanoparticle 12a. Note that in FIG. 2, MO represents a metal oxide (to be specific, the metal oxide nanoparticle 12a), and R, R¹, and R² each independently represent an organic residue. FIG. 3 shows the bond enthalpies of single bonds between bonding atoms at 298 K.

The reaction formula between the phosphonic acid and the surface hydroxyl group of the metal oxide nanoparticle 12a is represented by the following formulas (I-1) and (I-2):

M-OH+RPO(OH)₂→M-O—P(R)(O)OH+H₂O (I-1).

M-OH+M-O—P(R)(O)OH→M-O—P(R)(O)—O-M (I-2)

Note that in formulas (I-1) and (I-2), M represents a metallic atom in the metal oxide nanoparticle 12a. R represents an organic residue.

Suitable examples of the organic residue include a hydrogen atom, an alkyl group, or a fluoroalkyl group. Among them, the organic residue is more preferably a fluoroalkyl group, and preferably has fluorine at a terminal group.

The organic ligand 12b containing fluorine at a terminal group such as fluoroalkylphosphonic acid having a fluoroalkyl group as the organic residue has high liquid repellency. Thus, when such an organic ligand is used as the organic ligand 12b, it is possible to prevent a solvent (to be specific, a solvent contained in a coating liquid used for forming the ETL 12) from permeating into a lower layer and to protect the lower layer.

Accordingly, in a case where the ETL 12 including the organic ligand 12b including fluorine at a terminal group as the organic ligand 12b is provided on the EML 11 adjacently to the EML 11, permeation of a solvent into the EML 11 can be suppressed by a liquid-repellent action of fluorine. Thus, the EML 11 can be protected and damage to the EML 11 can be reduced.

The organic ligand 12b preferably contains a carbon chain having 6 or more and 10 or less carbon atoms in the main chain. Thus, the number of carbon atoms of the alkyl group or fluoroalkyl group is not particularly limited, but is preferably 6 or more and 10 or less.

In a case where the layer thickness of the ETL 12 and the particle size of the metal oxide nanoparticles 12a are the same, the longer the ligand chain length of the organic ligand 12b (to be specific, the carbon chain length of the organic ligand 12b), the lower the density of the metal oxide nanoparticles 12a in the ETL 12. As a result, the film density of the ETL 12 decreases, and the charge transporting property of the ETL 12 decreases accordingly. Also, in a case where the layer thickness of the ETL 12 and the particle size of the metal oxide nanoparticles 12a are the same, an increase in the length of the carbon chain in the organic ligand 12b causes an increase in insulators. thereby inhibiting charge injection. Thus, according to the study by the present inventors, when the number of carbon atoms in the carbon chain is 6 or more, a current is suppressed, the balance of carriers in the EML 11 is adjusted, the rate of non-light-emitting recombinations such as overflow and Auger decay of carriers is reduced, and the luminous efficiency is improved.

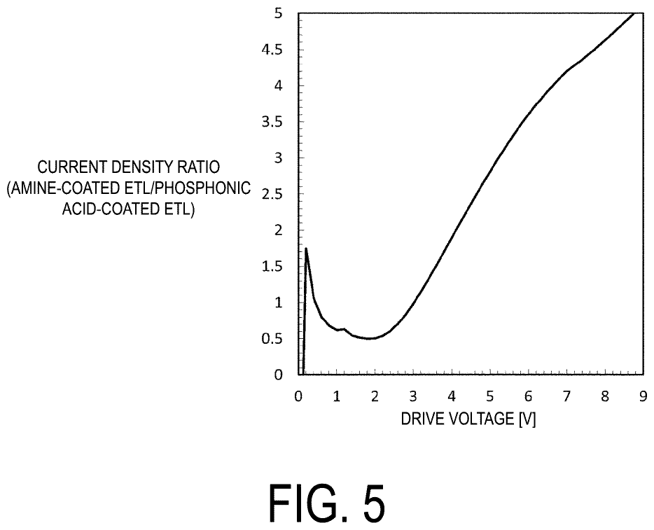

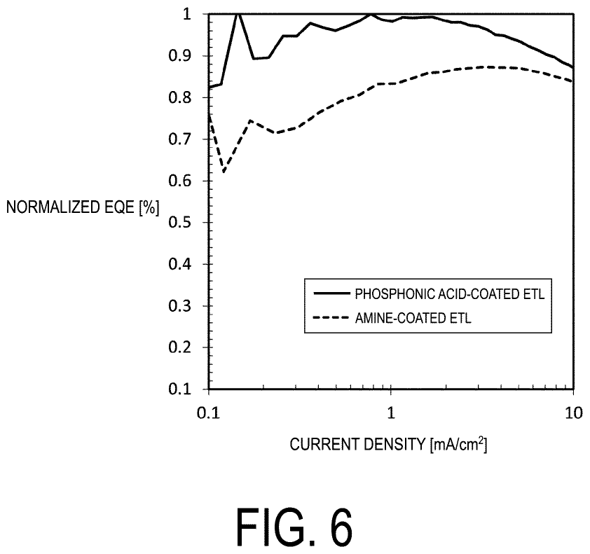

For example, the number of carbon atoms of monoethanolamine is 2 as shown in FIG. 2, and in a case where the number of carbon atoms is 6 or more as described above, the ligand chain length is more than twice that of monoethanolamine. Thus, in a case where an organic ligand containing a carbon chain having 6 or more and 10 or less carbon atoms in the main chain is used as the organic ligand 12b, the film density is lower than in a case where monoethanolamine is used as the organic ligand 12b, and the electrical characteristics and the luminous efficiency can be improved as shown in FIGS. 5 and 6 described below, for example.

On the other hand, when the length of the carbon chain in the organic ligand 12b is more than 10, the density of the metal oxide nanoparticles 12a in the ETL 12 becomes too small, and insulating components due to voids increase, whereby the insulating property tends to be high. This may hinder carrier transfer by a tunnel effect. Thus, the number of carbon atoms is preferably 6 or more and 10 or less.

Accordingly, as the organic ligand 12b, for example, at least one phosphonic acid selected from the group consisting of 1H,1H,2H,2H-perfluoro-n-hexylphosphonic acid (FHPA) represented by the following structural formula (1):

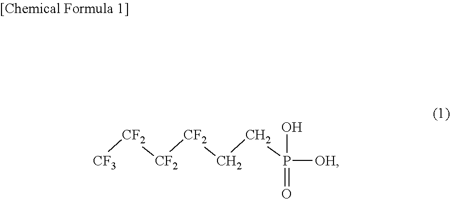 [SMILES: O=P(O)(O)CCC(F)(F)C(F)(F)C(F)(F)C(F)(F)F]

1H,1H,2H,2H-perfluoro-n-octylphosphonic acid (FOPA) represented by the following structural formula (2):

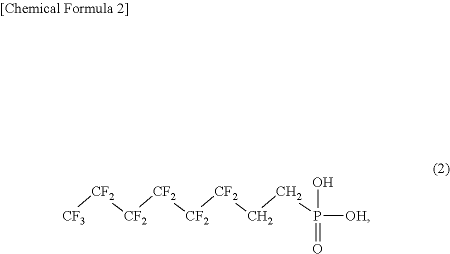 [SMILES: O=P(O)(O)CCC(F)(F)C(F)(F)C(F)(F)C(F)(F)C(F)(F)C(F)(F)F]

and
1H,1H,2H,2H-perfluoro-n-decylphosphonic acid (FDPA) represented by the following structural formula (3):

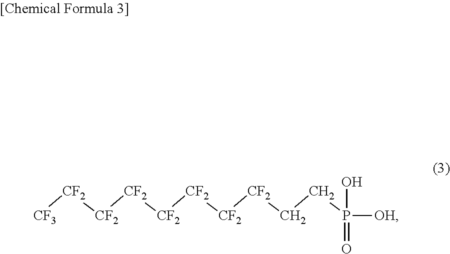 [SMILES: O=P(O)(O)CCC(F)(F)C(F)(F)C(F)(F)C(F)(F)C(F)(F)C(F)(F)C(F)(F)C(F)(F)F]

is preferable.

These FHPA, FOPA and FDPA each are a fluoroalkylphosphonic acid including a carbon chain having 6 or more and 10 or less carbon atoms in a main chain, including fluorine at a terminal group, having high liquid repellency, and being easily available.

As shown in formulas (I-1) and (I-2) above, the phosphonic acid reacts with the —OH group bonded to M in formulas (I-1) and (I-2), which is a surface hydroxyl group on the surface of the metal oxide nanoparticle 12a, to undergo dehydration-condensation. As a result, the OH group bonded to a phosphorus atom of the phosphonic (—PO(OH)₂) group is detached, and as shown in formulas (I-1) and (I-2) and FIG. 2, the phosphorus atom (P) of the phosphonic group is bonded to the oxygen atom (O) in the surface hydroxyl group on the surface of the metal oxide nanoparticle 12a. As shown in FIG. 3, the bond enthalpy at 298 K between a phosphorus atom and an oxygen atom (between P—O) is 363 kJ/mol.

The reaction formula between a carboxylic acid and the surface hydroxyl group of the metal oxide nanoparticle 12a is represented by the following formula (II):

M-OH+RCOOH→M-O—CO—R+H₂O (II).

Note that also in formula (II), M represents a metallic atom of the metal oxide nanoparticle 12a, and R represents an organic residue.

Also in this case, suitable examples of the organic residue include a hydrogen atom, an alkyl group, and a fluoroalkyl group. Among them, for the same reason as described above, the organic residue is more preferably a fluoroalkyl group, and preferably has fluorine at a terminal group. As described above, the organic ligand 12b preferably includes a carbon chain having 6 or more and 10 or less carbon atoms in the main chain. Thus, the number of carbon atoms of the alkyl group or fluoroalkyl group is not particularly limited, but is preferably 6 or more and 10 or less.

As represented by formula (II), similarly to the phosphonic acid, the carboxylic acid reacts with the —OH group bonded to M in formula (II), which is a surface hydroxyl group on the surface of the metal oxide nanoparticle 12a, and undergoes dehydration-condensation. Due to this, the —OH group bonded to a carbon atom of the carboxyl (—COOH) group is detached, and as shown by formula (II) and FIG. 2, the carbon atom (C) of the carboxyl group and the oxygen atom (O) in the surface hydroxyl group on the surface of the metal oxide nanoparticle 12a are bonded to each other. As shown in FIG. 3, the bond enthalpy at 298 K between the carbon atom and the oxygen atom (between C—O) is 358 kJ/mol.

The reaction formula between a silane and the surface hydroxyl group on the surface of the metal oxide nanoparticle 12a is represented by, for example, the following formula (III):

M-OH+R¹R²R¹Si—OX→M-O—Si-R¹R²R³+XOH (III).

Note that also in formula (III), M represents a metallic atom in the metal oxide nanoparticle 12a. R¹, R², R³, and X each independently represent an organic residue.

Among these organic residues, R¹ suitably represents a hydrogen atom, an alkyl group, or a fluoroalkyl group, R² and R³ suitably each independently represent an alkyl group, a fluoroalkyl group, an alkoxy group, or a hydroxy group, and X represents a hydrogen atom or an alkyl group.

Note that also in a case where the organic ligand 12b is a silane, the organic ligand 12b more preferably has a fluoroalkyl group, and preferably has fluorine in a terminal group, for the same reason as described above. In addition, also in a case where the organic ligand 12b is a silane, the organic ligand 12b preferably contains a carbon chain having 6 or more and 10 or less carbon atoms in the main chain for the same reason as described above.

As represented by formula (III), the silane reacts with, for example, the —OH group bonded to M in formula (III), which is a surface hydroxyl group on the surface of the metal oxide nanoparticle 12a, to be condensed (for example, dehydration-condensed). This detaches the —OX group (e.g., a hydroxy group) bonded to a silicon atom of the silanol group (Si—OX), and as shown by formula (III) and in FIG. 2, the silicon atom (Si) of the silanol group is bonded to the oxygen atom (O) in the surface hydroxyl group on the surface of the metal oxide nanoparticle 12a. As shown in FIG. 3, the bond enthalpy at 298 K between the silicon atom and the oxygen atom (between Si—O) is 466 kJ/mol. Note that FIG. 2 shows a case in which R³ is an alkoxy group or a hydroxy group as an example.

The reaction formula between an isocyanic acid and the surface hydroxyl group on the surface of the metal oxide nanoparticle 12a is represented by the following formula (IV):

M-OH+RNCO→M-CO—NH—R (IV).

Note that also in formula (IV), M represents a metallic atom in the metal oxide nanoparticle 12a. Each R independently represents an organic residue.

Also in this case, suitable examples of the organic residue include an alkyl group and a fluoroalkyl group. Among them, for the same reason as described above, the organic residue is more preferably a fluoroalkyl group, and preferably has fluorine at a terminal group. As described above, the organic ligand 12b preferably contains a carbon chain having 6 or more and 10 or less carbon atoms in the main chain. Thus, the number of carbon atoms of the alkyl group or fluoroalkyl group is not particularly limited, but is preferably 6 or more and 10 or less.

In the isocyanic acid, as represented by formula (IV), when a negatively charged hydroxide ion (OH⁻) on the surface of MO is nucleophilically added to the carbon atom of RNCO, the carbon atom (C) of RNCO is bonded to the oxygen atom (O) in the surface hydroxyl group on the surface of the metal oxide nanoparticle 12a as shown in formula (IV) and FIG. 2. As described above, the bond enthalpy at 298 K between the carbon atom and the oxygen atom (between C—O) is 358 kJ/mol.

On the other hand, monoethanolamine is coordinately bonded to the metal oxide nanoparticle 12a, and as shown in FIG. 3, the bond enthalpy at 298 K between the nitrogen atom and the oxygen atom (between N—O) is 214 kJ/mol. Due to this, as described above, the phosphonic acid, the carboxylic acid, the silane, and the isocyanic acid have high bond enthalpies, and are less likely to be detached from the metal oxide nanoparticle 12a due to energization, as compared with an amine-based organic ligand that bonds to the metal oxide nanoparticle 12a via an amino group. This can suppress a change in electrical characteristics by continuous driving.

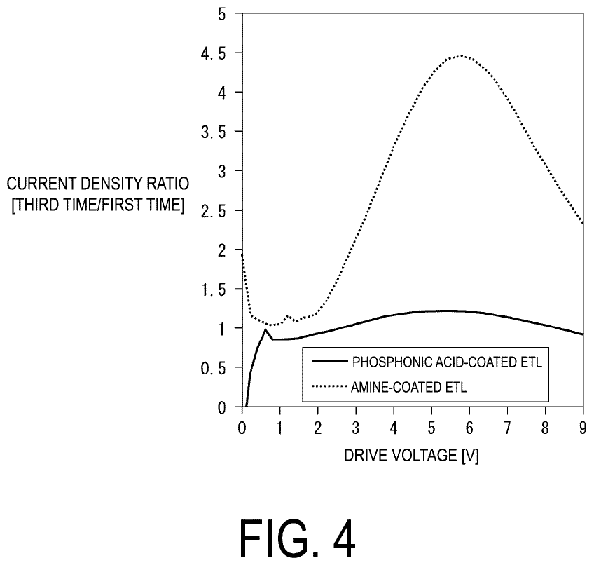

FIG. 4 is a graph showing a relationship between a drive voltage and a ratio of a current density in the third energization to a current density in the first energization (driving) when a current is applied to the light-emitting element for about 4 minutes each time in a case where FOPA, which is a phosphonic acid having a phosphonate group having a high bond enthalpy as a coordinating group, is used, and in a case where monoethanolamine having an amino group having a lower bond enthalpy as a coordinating group than that of the phosphonate group is used, as the organic ligand 12b.

FIG. 5 is a graph showing a relationship between a drive voltage and a current density ratio during the first driving of the light-emitting element in a case where in the ETL 12, monoethanolamine, which has a lower bond enthalpy than that of the phosphonic acid, is used as the organic ligand 12b, with respect to the case where the phosphonic acid, which has a high bond enthalpy as described above, is used as the organic ligand 12b.

FIG. 6 is a graph showing a relationship between a current density during the first driving of the light-emitting element and the external quantum efficiencies (EQEs) of the light-emitting elements in a case where in the ETL 12, the phosphonic acid, which is one type of organic ligand having 6 carbon atoms (carbon chain length) in the main chain, is used as the organic ligand 12b and in a case where monoethanolamine, which is one type of organic ligand having 2 carbon atoms (carbon chain length) in the main chain, is used.

Note that in FIG. 6, as the EQE, a normalized EQE is shown, which is obtained by normalization with the maximum EQE when the phosphonic acid having a carbon chain length of 6 is used in the ETL 12 set to 1.

In FIGS. 4 to 6, the case where monoethanolamine is used as the organic ligand 12b in the ETL 12 is referred to as “amine-coated ETL”, and the case where the phosphonic acid is used as the organic ligand 12b is referred to as “phosphonic acid-coated ETL”.

Note that in the measurements shown in FIGS. 4 to 6, a red QD that emits red light and includes InP as a core material and ZnS as a shell material was used as the QD 11a. An ammeter was used to measure the current density. The EQE was measured using an external quantum efficiency measuring apparatus.

As shown in FIG. 4, in the case where the phosphonic acid is used as the organic ligand 12b, the change in current density with respect to the number of times of driving is suppressed and the change in current density is particularly small in the light-emitting region, as compared with the case where monoethanolamine is used as the organic ligand 12b.

In this way, it can be seen that the organic ligand 12b having a larger bond enthalpy has a smaller change in current characteristics.

In addition, as shown in FIG. 5, when monoethanolamine is used as the organic ligand 12b, the current density in the light-emitting region tends to be higher than when the phosphonic acid is used as the organic ligand. As shown in FIG. 5, for example, in a case where a voltage of 5V is applied to the light-emitting element, when monoethanolamine is used as the organic ligand 12b, a current which is about 2.5 times as large as that in the case where the phosphonic acid is used as the organic ligand 12b flows.

Further, as shown in FIG. 6, in the case where the phosphonic acid having a carbon chain length of 6 is used as the organic ligand 12b, the EQE is improved, as compared with the case where monoethanolamine is used as the organic ligand 12b.

As described above, when the phosphonic acid is used as the organic ligand 12b, as compared with the case where monoethanolamine is used as the organic ligand 12b, it is possible to suppress the characteristic change in the current driving and to improve the EQE. Accordingly, when the phosphonic acid is used as the organic ligand 12b, the operation of the device can be stabilized and the luminous efficiency can be improved, as compared with the case where monoethanolamine is used as the organic ligand 12b.

Thus, from the results shown in FIGS. 5 and 6, it can be seen that when the carbon chain length of the organic ligand 12b is longer, the charge transporting capability can be reduced to adjust the carrier balance, whereby it is possible to improve the luminous efficiency such as the EQE.

Note that although FOPA described above is used as the phosphonic acid in FIGS. 4 to 6, the same result can be obtained even in a case where a phosphonic acid other than FOPA is used. As shown in FIGS. 4 to 6, phosphonic acids have high bond enthalpies and thus have high binding energies, bonding of the organic ligand 12b to the metal oxide nanoparticle 12a is strong, and phosphonic acids are less likely to be detached from the surface of the metal oxide nanoparticle 12a.

Accordingly, as the organic ligand 12b, a phosphonic acid or an organic ligand having a higher bond enthalpy at 298 K between bonding atoms at a bonding site between the organic ligand 12b and the surface hydroxyl group of the metal oxide nanoparticle 12a than that of the phosphonic acid is suitably used.

However, when the value of the bond enthalpy is within a range of ±10%, there is a similar tendency, and in particular, when the value is within a range of ±5%, a closer result is obtained.

For example, as described above, in a case where the organic ligand 12b is a phosphonic acid, the bond enthalpy at 298 K between bonding atoms at a bonding site between the organic ligand 12b and the surface hydroxyl group of the metal oxide nanoparticle 12a is 363 kJ/mol. In a range of 10% of 363 kJ/mol which is the bond enthalpy of this phosphonic acid, to be specific, in the range where the bond enthalpy is 326.7 kJ/mol or more and 399.3 kJ/mol or less, a tendency similar to that of the phosphonic acid is obtained. In particular, in a range of ±5% of the above-described bond enthalpy of the phosphonic acid, to be specific, in the range where the bond enthalpy is 344.85 kJ/mol or more and 381.15 kJ/mol or less, a result closer to that of the phosphonic acid is obtained.

In addition, as described above, in a case where the organic ligand 12b is the silane, the bond enthalpy at 298 K between bonding atoms at a bonding site between the organic ligand 12b and the surface hydroxyl group of the metal oxide nanoparticle 12a is 466 kJ/mol. In a range of ±10% of 466 kJ/mol, which is the bond enthalpy of this silane, to be specific, in the range where the bond enthalpy is 419.4 kJ/mol or more and 512.6 kJ/mol or less, a tendency similar to that of the silane is obtained. In particular, in a range of ±5% of the above-described bond enthalpy of the silane, to be specific, in the range where the bond enthalpy is 442.7 kJ/mol or more and 489.3 kJ/mol or less, a result closer to that of the silane is obtained.

Thus, the bond enthalpy at 298 K between bonding atoms at a bonding site between the organic ligand 12b and the surface hydroxyl group is preferably 326.7 kJ/mol or more.

As described above, the bond enthalpies of the phosphonic acid, the carboxylic acid, the silane, and the isocyanic acid are all 326.7 kJ/mol or more, and even in a case where any of the carboxylic acid, the silane, and the isocyanic acid is used as the organic ligand 12b, detachment of the organic ligand 12b due to energization can be suppressed and a change in electrical characteristics due to continuous driving can be suppressed as in the case of using the phosphonic acid as the organic ligand 12b. In addition, even in a case where any of the carboxylic acid, the silane, and the isocyanic acid is used as the organic ligand 12b, as compared with the case where monoethanolamine is used as the organic ligand 12b, it is possible to suppress the characteristic change in current driving and to improve the EQE. Thus, even in the case where any of the carboxylic acid, the silane, and the isocyanic acid is used as the organic ligand 12b, as compared with the case where monoethanolamine is used as the organic ligand 12b, the operation of the device can be stabilized and the luminous efficiency can be improved.

Accordingly, as described above, the organic ligand 12b may be at least one selected from the group consisting of carboxylic acids, silanes, and isocyanic acids, or may contain these organic ligands. However, the organic ligand 12b preferably contains a phosphonic acid, and is particularly preferably a phosphonic acid.

As described above, a phosphonic acid has a high bond enthalpy to the metal oxide nanoparticles 12a and is excellent in dispersibility of the metal oxide nanoparticles 12a in a solvent. Although the bond enthalpy of a silane is higher than that of a phosphonic acid, a phosphonic acid is less likely to be hydrolyzed and polymerized in a solution and has higher solution stability than that of a silane. In a case where a phosphonic acid is used as the organic ligand 12b, the density of the organic ligand 12b coordinated by forming a —OH group on the surface of the metal oxide nanoparticle 12a by proton transfer from a —OH group on the side not coordinated (bonded) to the metal oxide nanoparticle 12a in the organic ligand 12b is high. Thus, as the organic ligand 12b, a phosphonic acid is particularly preferable.

Note that the type and structure of the organic ligand 12b contained in the ETL 12 can be analyzed and identified by mass spectrometry such as time-of-flight secondary ion mass spectrometry (TOF-SIMS); elementary analysis such as Auger electron-spectroscopy (AES) and scanning electron microscope-energy dispersive X-ray spectrometry (SEM-EDX); and vibrational spectrometry such as Raman spectrometry and infrared spectrometry.

Note that a layer thickness of the ETL 12 in the light-emitting element 1 is not particularly limited, and may be set in a similar manner to the related art. In addition, a thickness of each of the layers other than the ETL 12 is not particularly limited, and may be set similarly to the related art.

### First Modified Example

FIG. 1 illustrates a case in which the light-emitting element 1 has a conventional structure in which the anode 2 is the lower layer electrode as an example. However, as described above, the light-emitting element 1 may have an inverted structure in which the cathode 3 is a lower layer electrode. FIG. 1 illustrates a case where the CTL is an ETL as an example. However, the CTL is not limited to the ETL, and may be a hole transport layer. Hereinafter, the hole transport layer will be denoted as the “HTL”.

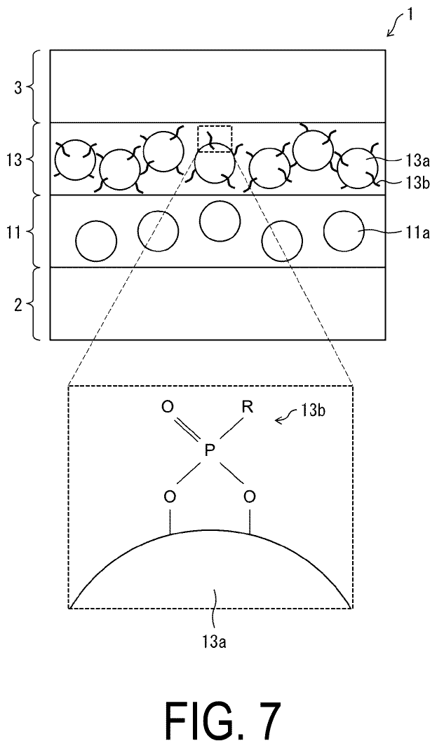

FIG. 7 is a cross-sectional view illustrating an example of a schematic configuration of a light-emitting element 1 according to the present modified example.

The light-emitting element 1 illustrated in FIG. 7 has a conventional structure in which the anode 2 is a lower layer electrode and the cathode 3 is an upper layer electrode, and has a configuration in which the anode 2, the EML 11, the HTL 13, and the cathode 3 are provided in this order from the lower layer side (e.g., a support body side not illustrated such as a substrate), as an example.

The HTL 13 is a CTL including a hole transporting material and having a hole transporting function of increasing hole transporting efficiency to the EML 11.

The HTL 13 illustrated in FIG. 7 includes a metal oxide nanoparticle 13a as a hole transporting material, and has a configuration in which an organic ligand 13b is chemically bonded to the metal oxide nanoparticle 13a via an —OH group (surface hydroxyl group) present on the surface of the metal oxide nanoparticle 13a. Thus, the HTL 13 illustrated in FIG. 7 includes the metal oxide nanoparticles 13a and the organic ligands 13b. Note that also in the present modified example, not only a molecule or an ion bonded to the surface of the metal oxide nanoparticle 13a but also a molecule or an ion that can be bonded but is not bonded is also called a “ligand”.

Examples of the metal oxide nanoparticles 13a include NiO nanoparticles, MgO nanoparticles, and MgNiO nanoparticles.

Also in the present modified example, as the organic ligand 13b, an organic ligand having a bond enthalpy at 298 K between bonding atoms at a bonding site between the organic ligand 13b and a surface hydroxyl group of the metal oxide nanoparticle 13a of 326.7 kJ/mol or more is used.

Accordingly, as the organic ligand 13b, an organic ligand similar to the organic ligand 12b can be used. FIG. 7 illustrates a case where the organic ligand 13b is a phosphonic acid as an example. However, the present modified example is not limited thereto, and similarly to the organic ligand 12b, the organic ligand 13b may be, for example, at least one selected from the group consisting of a carboxylic acid, a silane, and an isocyanic acid.

Thus, according to the present modified example, as described above, when the organic ligand 13b is chemically bonded to the metal oxide nanoparticle 13a via the surface hydroxyl group of the metal oxide nanoparticle 13a, in other words, when the HTL 13 contains the organic ligand 13b, it is possible to provide the light-emitting element 1 in which the bonding of the organic ligand 13b to the metal oxide nanoparticle 13a in the HTL 13 is strong. detachment of the organic ligand 13b from the surface of the metal oxide nanoparticle 13a in the HTL 13 due to energization is suppressed, and a change in electrical characteristics due to continuous driving can be suppressed.

### Second Modified Example

Note that in FIGS. 1 and 7, to simplify the description, the case where the light-emitting element includes the EML 11 as the function layer and the ETL 12 or the HTL 13 as the CTL is illustrated as an example. However, the present embodiment is not limited thereto, and both CTLs of the ETL 12 and the HTL 13 may be provided as the first CTL and the second CTL.

### Third Modified Example

The light-emitting element 1 according to the present embodiment may include a layer other than the EML 11 and the CTL as the function layer. Examples of such a function layer include a hole injection layer, an electron injection layer, an electron blocking layer, and a hole blocking layer.

### Fourth Modified Example

FIG. 7 illustrates the case where the anode 2, the EML 11, the HTL 13, and the cathode 3 are provided in this order from the lower layer side as an example. As described above, when the HTL 13 is provided on the EML 11 to be adjacent to the EML 11, in a case where, for example, an organic ligand including fluorine at a terminal group is used as the organic ligand 13b, it is possible to reduce damage to the EML 11 by the liquid-repellent action of fluorine.

However, the present modified example is not limited thereto, and the light-emitting element 1 may have a configuration in which the anode 2, the EML 11, the HTL 13, and the cathode 3 are provided in the order of the cathode 3, the EML 11, the HTL 13, and the anode 2 from the lower layer side, for example.

### Fifth Modified Example

In the present embodiment, description has been given using a case where the light-emitting element 1 is a QLED including a QD as a light-emitting material in the EML 11 as an example. However, the present embodiment is not limited thereto, and the light-emitting element 1 may be an OLED including an organic light-emitting material as a light-emitting material in the EML 11.

### Second Embodiment

Another embodiment of the disclosure will be described below. Further, members having the same functions as those of the members described in the above-described embodiments will be denoted by the same reference numerals and signs, and the description thereof will not be repeated for the sake of convenience of description.

The light-emitting element 1 can be suitably used as a light source for a light-emitting device such as a display device, an illumination device, or the like, for example. In the present embodiment, description will be given using a display device as an example of the light-emitting device according to the present embodiment.

In the following description, a case where the light-emitting element 1 is a QLED and has a conventional structure in which the anode 2 is a lower layer electrode and the cathode 3 is an upper layer electrode will be described as an example. However, the present embodiment is not limited thereto, and the light-emitting element 1 may have an inverted structure in which the cathode 3 is a lower layer electrode, and may be an OLED, for example.

### Schematic Configuration of Display Device

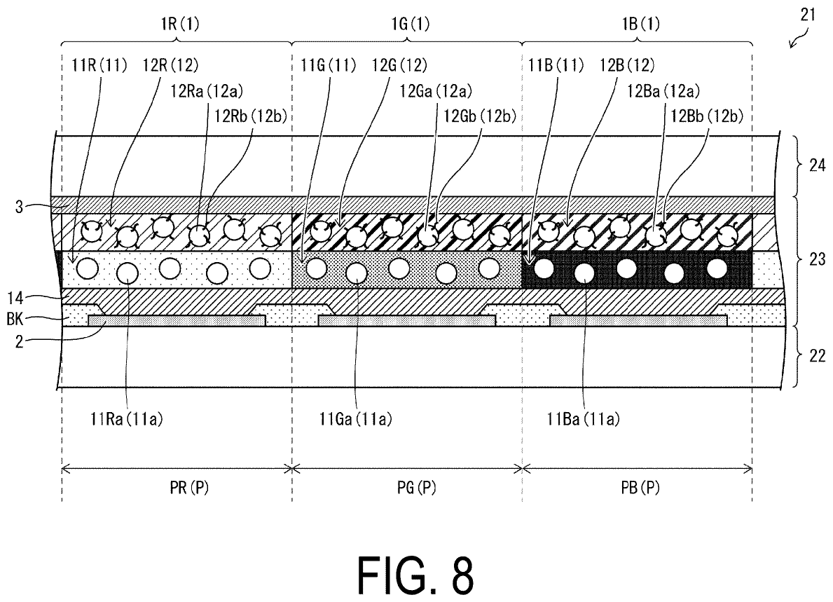

FIG. 8 is a cross-sectional view illustrating an example of a schematic configuration of main portions of a display device 21 (light-emitting device) according to the present embodiment.

The display device 21 includes a plurality of pixels P. Each pixel P is provided with the light-emitting element 1. The display device 21 illustrated in FIG. 1 includes, as a substrate 22, an array substrate formed with a drive element layer, and has a configuration in which a light-emitting element layer 23 including a plurality of light-emitting elements 1 having different light emission wavelengths, a sealing layer 24, and a function film not illustrated are layered in this order on the substrate 22.

The display device 21 illustrated in FIG. 8 includes, as the pixels P, a red pixel PR that emits red light, a green pixel PG that emits green light, and a blue pixel PB that emits blue light. A bank BK with insulating properties is provided between the pixels P.

The display device 21 includes the plurality of light-emitting elements 1 having different light emission wavelengths. The display device 21 includes, as the plurality of light-emitting elements 1, a red light-emitting element 1R (first light-emitting element), a blue light-emitting element 1B (second light-emitting element), and a green light-emitting element 1G (third light-emitting element). The red light-emitting element 1R emits red light (light of a first color). The blue light-emitting element 1B emits blue light (light of a second color). The green light-emitting element 1G emits green light (light of a third color).

In the red pixel PR (first pixel), the red light-emitting element 1R is provided as the light-emitting element 1. In the blue pixel PB (second pixel), the blue light-emitting element 1B is provided as the light-emitting element 1. In the green pixel PG (third pixel), the green light-emitting element 1G is provided as the light-emitting element 1.

In the disclosure, in a case that there is no particular need to distinguish between the red light-emitting element 1R, the green light-emitting element 1G, and the blue light-emitting element 1i, the red light-emitting element 1R, the green light-emitting element 1G, and the blue light-emitting element 1B are collectively referred to simply as “light-emitting elements 1”. Likewise, in the disclosure, in a case that there is no particular need to distinguish between the red pixel PR, the green pixel PG, and the blue pixel PB, the red pixel PR, the green pixel PG, and the blue pixel PB are collectively referred to simply as “pixels P”.

The light-emitting element layer 23 includes the plurality of light-emitting elements 1 respectively provided for respective pixels P, and has a structure in which each layer of the light-emitting elements 1 is layered over the substrate 22.

The substrate 22 functions as a support body for forming each layer of the light-emitting elements 1. The substrate 22 is an array substrate. The substrate 22 has, for example, a configuration in which a thin film transistor layer (TFT layer) having a plurality of thin film transistors (TFTs) is provided on an insulating substrate as a base substrate.

The insulating substrate may be, for example, an inorganic substrate made of an inorganic material such as glass, quartz, or ceramics, or a flexible substrate made primarily of a resin such as polyethylene terephthalate or polyimide. In a case where the insulating substrate is a flexible substrate, the insulating substrate may be made of a resin film (resin layer) such as a polyimide film.

Furthermore, a barrier layer may be provided on a surface of the insulating substrate to prevent foreign matter such as water and oxygen from entering the TFT layer and the light-emitting element layer 23. The barrier layer can be composed of, for example, a silicon oxide film, a silicon nitride film, or a silicon oxynitride film formed by a chemical vapor deposition (CVD) method, or of a layered film of these films.

Pixel circuits that control each light-emitting element 1 and a plurality of wiring lines connected to the pixel circuits are formed in the TFT layer. The pixel circuits are provided for each pixel P to correspond to the pixel P in a display region. The pixel circuits include a plurality of TFTs. The plurality of TFTs are electrically connected to a plurality of wiring lines including wiring lines such as gate wiring lines and source wiring lines. For these TFTs, a known structure can be employed, and the structure is not particularly limited.

A flattening film covering the plurality of TFTs is provided on the surface of the TFT layer so that the surfaces of the plurality of TFTs are planarized. The flattening film can be composed of, for example, an organic insulating material such as a polyimide resin or an acrylic resin.

The light-emitting element layer 23 includes a plurality of anodes 2 provided on the flattening film, a cathode 3, a function layer provided between the anodes 2 and the cathode 3, and the banks BK having insulating properties and covering the edge of each of the anodes 2.

In the display device 21, the anodes 2 serving as lower layer electrodes function as so-called pixel electrodes (island-shaped lower layer electrodes) and are provided on the substrate 22 in an island shape for each light-emitting element 1 (in other words, for each pixel). The cathode 3 serving as an upper layer electrode is provided as a common electrode (common upper electrode) in common to all the light-emitting elements 1 (in other words, all the pixels P). The light-emitting elements 1 function as light sources that light up each of the pixels P.

The banks BK are used as edge covers that cover the edges of the patterned lower layer electrodes and also function as pixel separation films. An insulating organic material can be used for the banks BK. The insulating organic material preferably contains a photosensitive resin. For example, a polyimide resin, an acrylic resin, and the like can be used as the insulating organic material. The banks BK are formed in a lattice pattern, for example, in a plan view to surround each of the pixels P.

The light-emitting element layer 23 is provided with light-emitting elements 1 corresponding to respective pixels P. Each anode 2 serving as the lower layer electrode is electrically connected to the TFT of the substrate 22.

The red light-emitting element 1R illustrated in FIG. 8 has a configuration in which an anode 2 (second electrode), an HTL 14, an EML 11R, an ETL 12R, and a cathode 3 (first electrode) are layered in this order from the substrate 22 side. The green light-emitting element 1G illustrated in FIG. 8 has a configuration in which an anode 2, an HTL 14, an EML 11G, an ETL 12G, and a cathode 3 are layered in this order from the substrate 22 side. The blue light-emitting element 1B illustrated in FIG. 8 has a configuration in which an anode 2, an HTL 14, an EML 11, an ETL 12B, and a cathode 3 are layered in this order from the substrate 22 side.

The EML 11R is a red EML that emits red light, and is formed in an island shape in the red pixel PR. The EML 11G is a green EML that emits green light and is formed in an island shape in the green pixel PG. The EML 11B is a blue EML that emits blue light and is formed in an island shape in the blue pixel PB. The EML 11R, the EML 11G, and the EML 11B may be in contact with each other as illustrated in FIG. 8 or may be separated from each other.

The EML 11R contains QDs 11Ra as QDs 11a. The QDs 11Ra are red QDs that emit red light. The EML 11G contains QDs 11Ga as QDs 11a. The QDs 11Ga are green QDs that emit green light. The EML 11B contains QDs 11Ba as QDs 11a. The QDs 11Ba are blue QDs that emit blue light. The same light-emitting elements 1 (the same pixels P) have the same type of QDs Ila. As described above, in the QDs Ila, the emission wavelength can be controlled from a blue wavelength region to a red wavelength region by appropriately adjusting the particle size and composition of the QDs 11a.

Note that here, the blue light refers to, for example, light having an emission peak wavelength in a wavelength band of 400 nm or greater and 500 nm or less. The green light refers to, for example, light having an emission peak wavelength in a wavelength band of greater than 500 nm and 600 nm or less. The red light refers to light having an emission peak wavelength in a wavelength band of greater than 600 nm and 780 nm or less.

The ETL 12R is formed in an island shape in the red pixel PR. The ETL 12G is formed in an island shape in the green pixel PG. The ETL 12B is formed in an island shape in the blue pixel PB. The ETL 12R, the ETL 12G, and the ETL 12B may also be in contact with each other as illustrated in FIG. 8, or may be separated from each other.

The ETL 12R contains a metal oxide nanoparticle 12Ra as the metal oxide nanoparticle 12a and an organic ligand 12Rb as the organic ligand 12b. The ETL 12G contains a metal oxide nanoparticle 12Ga as the metal oxide nanoparticle 12a and an organic ligand 12Gb as the organic ligand 12b. The ETL 12B contains a metal oxide nanoparticle 12Ba as the metal oxide nanoparticle 12a and an organic ligand 12Bb as the organic ligand 12b.

As the metal oxide nanoparticle 12Ra, the metal oxide nanoparticle 12Ga, and the metal oxide nanoparticle 12Ba, the above-described metal oxide nanoparticle 12a can be used. The metal oxide nanoparticle 12Ra, the metal oxide nanoparticle 12Ga, and the metal oxide nanoparticle 12Ba may be the same as each other or different from each other.

As the organic ligand 12Rb, the organic ligand 12Gb, and the organic ligand 12Bb, the above-described organic ligand 12b can be used. The organic ligand 12Rb, the organic ligand 12Gb, and the organic ligand 12Bb may be the same as each other or different from each other.

Note that hereinafter, a case in which the ETL 12R, the ETL 12G, and the ETL 12B contain different materials will be described as an example. In this manner, the light-emitting device according to the present embodiment may include, as the light-emitting element 1, for example, a first light-emitting element and a second light-emitting element that emit light of different colors, and the charge transport layer of the first light-emitting element and the charge transport layer of the second light-emitting element may contain different materials. With this configuration, it is possible to provide a light-emitting device in which the first light-emitting element and the second light-emitting element include charge transport layers made of materials different from each other.

Note that in the present embodiment, in a case that there is no particular need to distinguish between the EML 11R, the EML 11G, and the EML 11B, the EML 11R, the EML 11G, and the EML 11B are collectively referred to simply as “EMLs 11”. In a similar manner, in the disclosure, in a case where there is no particular need to distinguish between the ETL 12R, the ETL 12G, and the ETL 12B, the ETL 12R, the ETL 12G, and the ETL 12B are collectively referred to simply as “ETLs 12”.

In addition, the HTL 14 illustrated in FIG. 8 is a common CTL provided in common to all the light-emitting elements 1. The HTL 14 illustrated in FIG. 8 may have the same configuration as that of the HTL 13 illustrated in FIG. 7, and an organic material may be used as a hole transporting material.

In a case where an organic material is used as the hole transporting material in the HTL 14, examples of the organic material include conductive polymer materials such as poly[(9,9-dioctylfluorenyl-2,7-diyl)-co-(4,4′-(N-(4-sec-butylphenyl)diphenylamine))](TFB), poly(3,4-ethylenedioxythiophene)-poly(styrenesulfonate) (PEDOT-PSS), and poly(N-vinylcarbazole) (PVK).

The light-emitting element layer 23 is covered by the sealing layer 24. The sealing layer 24 has translucency. The light-emitting elements 1 are sealed by the sealing layer 24, and thus water, oxygen, or the like can be prevented from permeating into the light-emitting elements 1. The sealing layer 24 may have, for example, a configuration in which an organic sealing film is interposed between inorganic sealing films, or may be a single layer of an inorganic sealing film. Alternatively, the sealing layer 24 may be sealing glass, for example.

In addition, as illustrated in FIG. 8, the display device 21 may include, on the sealing layer 24, a function film having at least one of an optical compensation function, a touch sensor function, and a protection function, for example.

### Manufacturing Method for Display Device 21

Next, a manufacturing method for the display device 21 described above will be described.

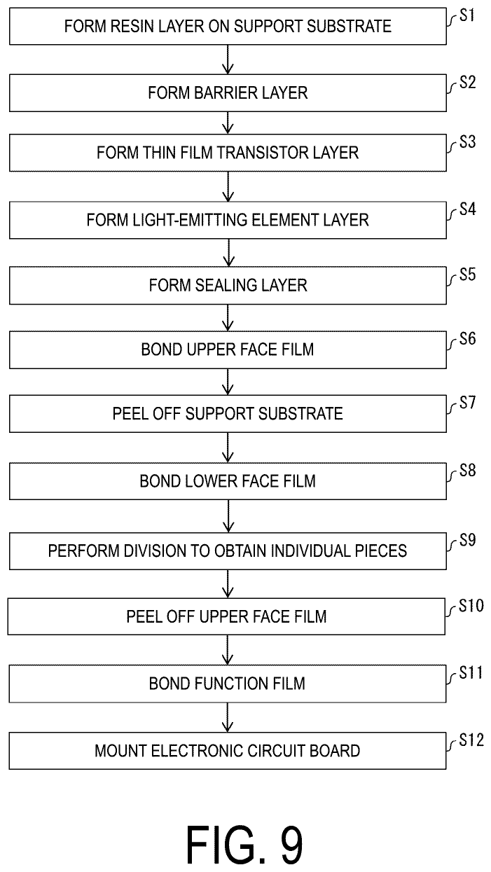

FIG. 9 is a flowchart showing an example of the manufacturing method for the display device 21 according to the present embodiment.

In a case where a flexible display device is manufactured as the display device 21, as shown in FIG. 9, first, a resin layer that will serve as an insulating substrate for the substrate 22 is formed on a light-transmissive support substrate (for example, mother glass), which is not illustrated (step S1). Next, a barrier layer is formed (step S2). Next, a thin film transistor layer (TFT layer) is formed (step S3). Next, the light-emitting element layer 23 is formed (step S4; light-emitting element forming step). Next, the sealing layer 24 is formed (step S5). Next, an upper face film for protection, which is not illustrated, is temporarily bonded onto the sealing layer 24 (step S6). Next, the support substrate is peeled from the resin layer through irradiation with laser light or the like (step S7). Next, a lower face film, which is not illustrated, is bonded to the lower face of the resin layer (step S8). Next, a layered body including the lower face film, the resin layer, the barrier layer, the TFT layer, the light-emitting element layer 23, the sealing layer 24, and the upper face film is divided to obtain a plurality of individual pieces (step S9). Next, the upper face film is peeled from the obtained individual pieces (step S10), and then a function film not illustrated is bonded (step S11). Next, an electronic circuit board (for example, an IC chip, an FPC, or the like), which is not illustrated, is mounted on a portion (a terminal portion) of the outer side (frame region) of the display region in which a plurality of pixels P are formed (pixel region) (step S12). Note that steps S1 to S12 are performed by a manufacturing apparatus of the display device 21 (including a film formation apparatus that performs each step of steps S1 to S5).

The upper face film is bonded onto the sealing layer 24 as described above and functions as a support material when the support substrate is peeled off. Examples of the upper face film include a polyethylene terephthalate (PET) film and the like. The lower face film is, for example, a PET film for achieving the display device 21 having excellent flexibility by being bonded to the lower face of the resin layer after the support substrate is peeled off. Note that the resin layer and the barrier layer are as described above.

Although the manufacturing method for the display device 21 having flexibility has been described above, generally, formation of the resin layer, replacement of a base material, and the like are not required for manufacturing the display device 21 having no flexibility. For this reason, for example, in a case that the display device 21 having no flexibility is to be manufactured, the layering step of steps S2 to S5 is performed on a glass substrate, after which the process proceeds to step S9.

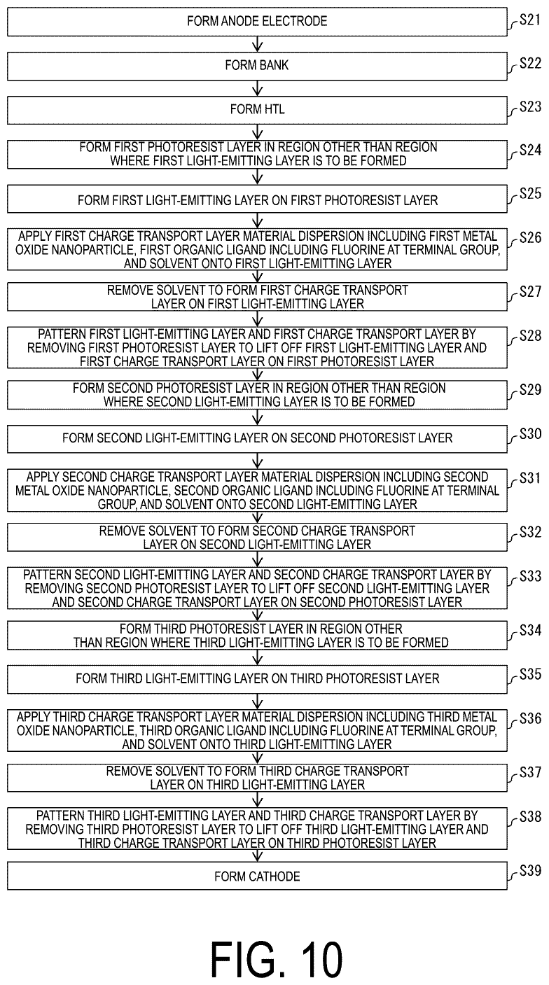

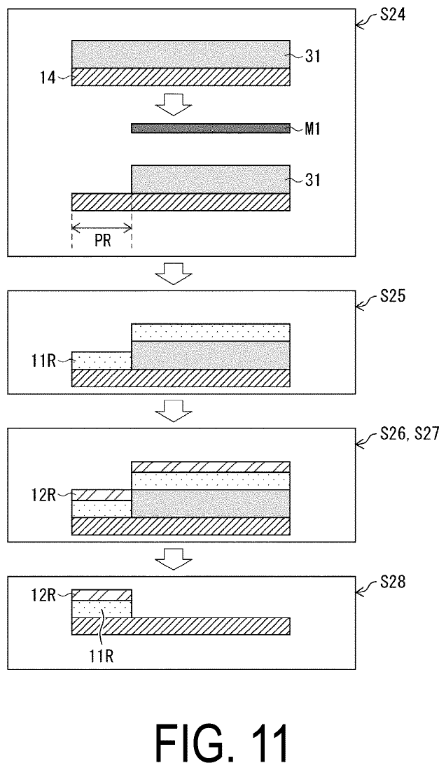

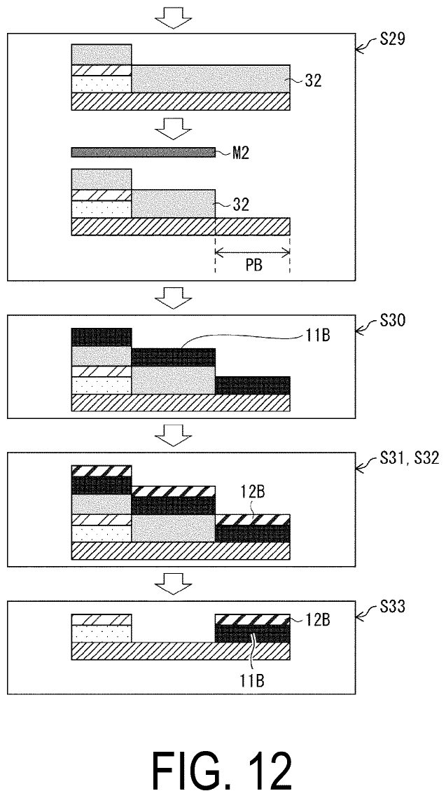

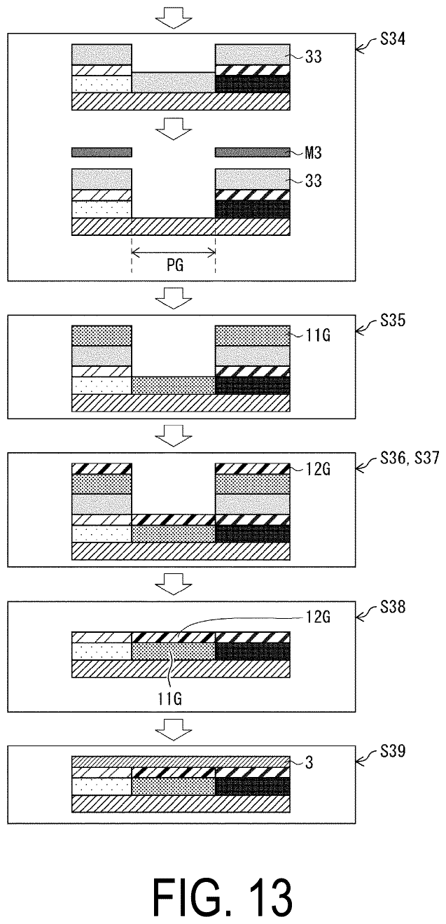

FIG. 10 is a flowchart showing an example of a step of forming the light-emitting element layer 23 indicated in step S4 illustrated in FIG. 3. FIG. 11 is a cross-sectional view illustrating an example of steps S24 to S28 shown in FIG. 10. FIG. 12 is a cross-sectional view illustrating an example of steps S29 to S33 shown in FIG. 10. FIG. 13 is a cross-sectional view illustrating an example of steps S34 to S38 shown in FIG. 10.

In FIGS. 11 to 13, a case where the display device 21 has the configuration illustrated in FIG. 8 will be described as an example. In addition, in FIGS. 11 to 13, a case where the EML 11R and the ETL 12R, the EML 11G and the ETL 12G, and the EML 11B and the ETL 12B are formed in the order of the red pixel PR, the blue pixel PB, and the green pixel PG will be described as an example. However, a formation order of the EML 11R and the ETL 12R, the EML 11G and the ETL 12G, and the EML 11B and the ETL 12B is not limited to the above order.

In the step of forming the light-emitting element layer 23 (step S4), the anode 2 is first formed, as a lower layer electrode, on the substrate 22 (to be specific, on the TFT layer formed in step S3) as shown in FIG. 10 (step S21). Step S21 is a step of forming the lower layer electrode. A vapor deposition method, a sputtering method, or the like, for example, is used for forming the anode 2 (film formation). The anode 2 is a pixel electrode formed in an island shape for each pixel P as described above, and is patterned for each pixel P. At this time, the anode 2 may be formed by, for example, forming a film with a conductive material in a solid state over the entire pixel region (display region) and then patterning the film for each pixel P by using a photolithography method or the like.

Next, a bank BK is formed to cover an edge of the anode 2 (step S22). The bank BK can be formed in a desired shape by, for example, for example, applying an insulating organic material such as a photosensitive resin to the entire pixel region in a solid state by using a sputtering method, a vapor deposition method, or the like, and then patterning the insulating organic material in the photolithography method or the like.

Next, the HTL 14 is formed (step S23). For the formation of the HTL 14, for example, a coating method, a sputtering method, a sol-gel method, or the like is used. In FIG. 8, a solid HTL is formed over the entire pixel region as the HTL 14.

Next, as illustrated in FIG. 10 and FIG. 11, a first photoresist layer 31 is formed as a template for lift-off with an opening in the region corresponding to the red pixel PR (first pixel) through photolithography (step S24). To be specific, first, the first photoresist layer 31 is formed in a solid state over the entire pixel region on the HTL 14 serving as a base layer. Next, by using a mask M1 with an opening in the region corresponding to the red pixel PR, exposure is performed with ultraviolet rays (UV), and then development is performed with a developer. This forms the patterned first photoresist layer 31 in a region other than the red pixel PR which is a region where the EML 11R (red EML, first light-emitting layer) is to be formed.

Next, on the HTL 14 on which the first photoresist layer 31 is formed, the EML 11R is formed in a solid state over the entire pixel region (step S25). Step S25 is a step of forming a light-emitting layer in the red light-emitting element 1R.

In step S25, a red QD dispersion containing red QDs and a solvent is applied in a solid state onto the HTL 14 on which the first photoresist layer 31 is formed to form a coating film of the red QD dispersion, and then, the solvent is removed by heating the coating film, or the like. This forms the EML 11R (red QD film) in a solid state covering the first photoresist layer 31 is formed on the HTL 14. As the solvent, for example, a non-polar solvent such as hexane, cyclohexane, or octane is used. For the application of the red QD dispersion, for example, a spin coating is used.

Next, a first charge transport layer material dispersion containing a metal oxide nanoparticle 12Ra (first metal oxide nanoparticle), an organic ligand 12Rb (first organic ligand) containing fluorine at a terminal group, and a solvent is applied onto the EML 11R (step S26). This forms a coating film of the first charge transport layer material dispersion.

The organic ligand 12Rb is chemically bonded to the metal oxide nanoparticle 12Ra via the surface hydroxyl group of the metal oxide nanoparticle 12Ra, and the bond enthalpy at 298 K between bonding atoms at a bonding site between the organic ligand 12Rb and the surface hydroxyl group is 326.7 kJ/mol or more. Examples of the solvent include fluorine-based polar solvents such as “Novec (trade name) 7200” (product number) available from 3M Company, 1,1,1,2,2,2,3,3,4,4,5,5,6,6-tridecafluorooctane (e.g., “ASAHIKLIN AC-6000” (trade name) available from AGC Inc.), and perfluorohexane, 1H,1H,2H,2H-heptadecafluorodecylamine.

Next, the solvent contained in the coating film (that is, applied first charge transport layer material dispersion) is removed by heating or the like to dry the coating film. This forms the ETL 12R (first charge transport layer, first electron transport layer) on the EML 11R (step S27).

Next, the first photoresist layer 31 is removed with an organic solvent to lift off the EML 11R and the ETL 12R on the first photoresist layer 31. Thereby, the EML 11R and the ETL 12R are patterned, and the EML 11R and the ETL 12R in the region other than the red pixel PR are removed (step S28). As a result, the EML 11R and the ETL 12R which have been patterned in an island shape are formed in the red pixel PR.

Next, the same steps as steps S24 to S28 are repeated for the blue pixel PB and the green pixel PG. Thereby, the EML 11B and the ETL 12B which have been patterned in an island shape are formed in the blue pixel PB, and the EML 11G and the ETL 12G which have been patterned in an island shape are formed in the green pixel PG.

Specifically, after step S28, as illustrated in FIG. 10 and FIG. 12, a second photoresist layer 32 is formed through photolithography as a template for lift-off with an opening of the blue pixel PB (second pixel) (step S29). To be specific, first, the second photoresist layer 32 is formed in a solid state over the entire pixel region to cover the ETL 12R on the HTL 14 serving as a base layer. Next, by using a mask M2 in which the region corresponding to the blue pixel PB is opened, exposure is performed with UV, and then development is performed with a developer. Thereby, the patterned second photoresist layer 32 is formed in a region other than the blue pixel PB which is a region where the EML 11B (blue EML, second light-emitting layer) is to be formed.

Next, on the HTL 14 on which the second photoresist layer 32 and the ETL 12R are formed, the EML 11B is formed in a solid state over the entire pixel region (step S30). Step S30 is a step of forming a light-emitting layer in the blue light-emitting element 1B.

In step S30, a blue QD dispersion containing blue QDs and a solvent is applied in a solid state onto the HTL 14 on which the second photoresist layer 32 and the ETL 12R are formed to form a coating film of the blue QD dispersion, and then the solvent contained in the coating film is removed by heating the coating film, or the like. This forms the EML 11B (blue QD film) in a solid state covering the second photoresist layer 32 on the HTL 14. As the solvent, a nonpolar solvent similar to the nonpolar solvent used in the red QD dispersion is used. For the application of the blue QD dispersion, for example, a spin coating method is used.

Next, a second charge transport layer material dispersion containing a metal oxide nanoparticle 12Ba (second metal oxide nanoparticle), an organic ligand 12Bb (second organic ligand) including fluorine at a terminal group, and a solvent is applied onto the EML 11B (step S31). This forms a coating film of the second charge transport layer material dispersion.

The organic ligand 12Bb is chemically bonded to the metal oxide nanoparticle 12Ba via the surface hydroxyl group of the metal oxide nanoparticle 12Ba, and the bond enthalpy at 298 K between bonding atoms at a bonding site between the organic ligand 12Bb and the surface hydroxyl group is 326.7 kJ/mol or more. As the solvent, a fluorine-based polar solvent similar to the fluorine-based polar solvent used in the first charge transport layer material dispersion is used.

Next, the solvent contained in the coating film (that is, applied second charge transport layer material dispersion) is removed by heating or the like to dry the coating film. This forms the ETL 12B (second charge transport layer, second electron transport layer) on the EML 11B (step S32).

Then, the second photoresist layer 32 is removed with an organic solvent to lift off the EML 11B and the ETL 12B on the second photoresist layer 32. Thereby, the EML 11B and the ETL 12B are patterned to remove the EML 11B and the ETL 12B in the region other than the blue pixel PB (step S33). This forms the EML 11B and the ETL 12B which have been patterned in an island shape are formed in the blue pixel PB.

Next, as illustrated in FIG. 10 and FIG. 13, the third photoresist layer 33 is formed through photolithography as a template for lift-off with an opening in the region corresponding to the green pixel PG (third pixel) (step S34). To be specific, first, the third photoresist layer 33 is formed in a solid state over the entire pixel region to cover the ETL 12R and the ETL 12B on the HTL 14 serving as a base layer. Next, by using a mask M3 with an opening in the region corresponding to the green pixel PG, exposure is performed with UV, and then development is performed with a developer. Thereby, the patterned third photoresist layer 33 is formed in a region other than the green pixel PG which is a region where the EML 11G (green EML, third light-emitting layer) is to be formed.

Next, on the third photoresist layer 33 and the HTL 14 on which the ETL 12R and the ETL 12B are formed, an EML 11G is formed in a solid state over the entire pixel region (step S35). Step S35 is a step of forming a light-emitting layer in the green light-emitting element 1G.

In step S35, a green QD dispersion containing green QDs and a solvent is applied in a solid state on the third photoresist layer 33 and the HTL 14 on which the ETL 12G is formed to form a coating film of the green QD dispersion, and then the solvent contained in the coating film is removed by heating the coating film, or the like. This forms the EML 11G (green QD film) in a solid state covering the third photoresist layer 33 on the HTL 14. As the solvent, a nonpolar solvent similar to the nonpolar solvent used for the red QD dispersion and the blue QD dispersion is used. For the application of the green QD dispersion, for example, spin coating is used.

Next, a third charge transport layer material dispersion containing a metal oxide nanoparticle 12Ga (third metal oxide nanoparticle), an organic ligand 12Gb (third organic ligand) including fluorine at a terminal group, and a solvent is applied onto the EML 11G (step S36). This forms a coating film of the third charge transport layer material dispersion.

The organic ligand 12Gb is chemically bonded to the metal oxide nanoparticle 12Ga via the surface hydroxyl group of the metal oxide nanoparticle 12Ga, and the bond enthalpy at 298 K between bonding atoms at a bonding site between the organic ligand 12Gb and the surface hydroxyl group is 326.7 kJ/mol or more. As the solvent, a fluorine-based polar solvent similar to the fluorine-based polar solvent used in the first charge transport layer material dispersion and the second charge transport layer material dispersion is used.

Next, the solvent contained in the coating film (that is, applied third charge transport layer material dispersion) is removed by heating or the like to dry the coating film. This forms the ETL 12G (third charge transport layer, third electron transport layer) on the EML 11G (step S37).

Then, the third photoresist layer 33 is removed with an organic solvent to lift off the EML 11G and the ETL 12G on the third photoresist layer 33. Thereby, the EML 11G and the ETL 12G are patterned to remove the EML 11G and the ETL 12G in a region other than the green pixel PG (step S38). This forms the EML 11G and the ETL 12G which have been patterned in an island shape are formed in the green pixel PG.

As a developer used in steps S24, S29, and S34, for example, an aqueous alkaline developer (aqueous alkaline solution) such as an aqueous tetramethylammonium hydroxide (TMAH) solution is used.

Note that, in FIGS. 11 to 13, a case where a positive-working photoresist is used for each of the first photoresist layer 31, the second photoresist layer 32, and the third photoresist layer 33 is illustrated as an example. However, the present embodiment is not limited to this example, and a negative-working photoresist may be used instead of the positive-working photoresist. However, the solubility of the negative-working photoresist with respect to the developing solution is reduced by exposure. Thus, in a case where a negative-working photoresist is used, a mask in which the opening region and the non-opening region are reversed only need be used as each of the masks described above.

In addition, examples of the organic solvent (resist solvent) used in steps S27, S32, and S37 include a non-aqueous polar solvent such as dimethylsulfoxide (DMSO).

Next, the cathode 3 is formed on the ETL 12R, the ETL 12G, and the ETL 12B as illustrated in FIG. 13 (step S39). Step S39 is a step of forming the upper layer electrode. A vapor deposition method, a sputtering method, or the like, for example, is used for forming the cathode 3 (film formation). The cathode 3 is a common electrode and is formed in a solid state on the ETL 12R, the ETL 12G, and the ETL 12B.

In this manner, the light-emitting element layer 23 is formed, which includes the plurality of light-emitting elements 1 including the red light-emitting element 1R, the green light-emitting element 1G, and the blue light-emitting element 1B and in which the ETL 12 is provided for each of the light-emitting elements 1.

In general, a lift-off method has an advantage that high definition is easily achieved as compared with an inkjet method. However, a photoresist is soluble in a polar solvent, such as the resist solvent described above. Thus, when an organic ligand including no fluorine at a terminal group such as monoethanolamine is used, the photoresist layer is dissolved at the stage where the charge transport layer material dispersion is applied onto the photoresist layer.

Accordingly, in a case where an organic ligand including no fluorine at a terminal group is used, the EML 11 and the ETL 12 cannot be lifted off at the same time as described above, and it is necessary to repeat the application of the QD dispersion and the lift-off of the EML 11 for each pixel P and then apply the charge transport layer material dispersion. Thus, a different charge transport layer material dispersion cannot be used for each pixel P, and a charge transport layer material dispersion suitable for each emission color cannot be used. In addition, the ETL 12 is formed by directly applying the charge transport layer material dispersion onto the EML 11, and thus the EML 11 comes into contact with the polar solvent used in the charge transport layer material dispersion to be damaged.

On the other hand, in a case where the ETL 12 is formed by an inkjet method, a charge transport layer material dispersion suitable for each emission color can be used. However, the inkjet method is not suitable for high definition and requires the use of a solvent having a high viscosity and a high boiling point.

However, the organic ligand including fluorine at a terminal group has high liquid repellency and can prevent the solvent from permeating into the lower layer to protect the lower layer. For this reason, according to the present embodiment, as described above, by using an organic ligand including fluorine at a terminal group as the organic ligand 12Rb, the organic ligand 12Gb, and the organic ligand 12Bb, the photoresist layer is not dissolved by the application of the charge transport layer material dispersion. Thus, the EML 11 and the ETL 12 can be lifted off at the same time to simplify the process, and damage to the EML 11 can be prevented. Further, the EML 11 and the ETL 12 can be lifted off at the same time in this manner, and thus it is possible to use a charge transport layer material dispersion suitable for each emission color. In addition, the lift-off method can be used to form the ETL 12, and thus high definition can be achieved.

In general, the conduction band lower end (equivalent to an electron affinity) of the QDs changes depending on the wavelength (emission wavelength) of light emitted from the QDs. Particularly, the conduction band lower end of the QDs has a deeper energy level as the wavelength of light emitted from the QDs is longer, and has a shallower energy level as the wavelength of light emitted from the QDs is shorter. This is because QDs with a smaller band gap have a deeper conduction band lower end.

Thus, the electron injection barrier from the ETL 12 to the EML 11 becomes larger when the emission wavelength becomes shorter. Accordingly, to balance carriers, it is desirable that the density of the metal oxide nanoparticles 12a in the ETL 12 is relatively high when the emission wavelength is shorter, the density of the metal oxide nanoparticles 12a in the ETL 12 is relatively low when the emission wavelength is longer, and the electron injection efficiency is improved when the emission wavelength is shorter. For this purpose, it is preferable to increase the ligand chain length of the organic ligand 12b when the emission wavelength is longer. According to the present embodiment, the charge injection amount (electron injection amount in the example illustrated in FIG. 8) can be controlled for each emission color by using a suitable charge transport layer material dispersion for each emission color as described above.

As described above, according to the present embodiment, the problems of the lift-off method and the inkjet method can be solved, and the advantages of the lift-off method and the inkjet method can be enjoyed.

Note that in the present embodiment, as described above, a case where each light-emitting element 1 has a conventional structure has been described as an example. However, as described above, each light-emitting element 1 may have an inverted structure, and an HTL may be formed as the CTL according to the disclosure.

In addition, FIG. 8 illustrates a case where the HTL 14 is provided between the EML 11R, the EML 11G, and the EML 11B and each of the anodes 2 as a base layer of the EML 11R, the EML 11G, and the EML 11B as an example. However, the present embodiment is not limited thereto. The EML 11R, the EML 11G, and the EML 11B may be separated by the bank BK. In a case where an ETL is formed as the CTL according to the disclosure, the HTL 14 does not necessarily need to be provided. Although not illustrated, the bank BK may have a height that separates the EMLs 11 of adjacent pixels P from each other, or may have a height that separates the EMLs 11 of adjacent pixels P from each other and separates the ETLs 12 of adjacent pixels P from each other.

In addition, in FIGS. 10 to 13, a case where the EML 11R and the ETL 12R, the EML 11B and the ETL 12B, and the EML 11G and the ETL 12G are formed in the order of the red pixel PR, the blue pixel PB, and the green pixel PG has been described as an example. However, the order of forming the EML 11R and the ETL 12R, the EML 11B and the ETL 12B, and the EML 11G and the ETL 12G, that is, in which pixel P each EML 11 and each ETL 12 are formed first is not particularly limited.

In the present embodiment, when two light-emitting layers among a plurality of light-emitting layers are compared, a light-emitting layer formed first is referred to as a first light-emitting layer, and a light-emitting layer formed later than the first light-emitting layer is referred to as a second light-emitting layer. In a case where three light-emitting layers are compared, a light-emitting layer formed first is referred to as a first light-emitting layer, a light-emitting layer formed next is referred to as a second light-emitting layer, and a light-emitting layer formed next is referred to as a third light-emitting layer.

In addition, a light-emitting element having the first light-emitting layer is referred to as a first light-emitting element, and a charge transport layer, a metal oxide nanoparticle, and an organic ligand included in the first light-emitting element are referred to as a first charge transport layer, a first metal oxide nanoparticle, and a first organic ligand, respectively. The charge transport layer material dispersion and the photoresist layer used for forming the first charge transport layer are referred to as a first charge transport layer material dispersion and a first photoresist layer, respectively. The pixel forming the first light-emitting element is referred to as a first pixel.

Note that the same applies to the second light-emitting element, the second charge transport layer, the second metal oxide nanoparticle, the second organic ligand, the second charge transport layer material dispersion, the second photoresist layer, and the second pixel. That is, in the present embodiment, the light-emitting element having the second light-emitting layer is referred to as a second light-emitting element, and the charge transport layer, the metal oxide nanoparticle, and the organic ligand included in the second light-emitting element are referred to as a second charge transport layer, a second metal oxide nanoparticle, and a second organic ligand, respectively. The charge transport layer material dispersion and the photoresist layer used for forming the second charge transport layer are referred to as a second charge transport layer material dispersion and a second photoresist layer, respectively, and the pixel forming the second light-emitting element is referred to as a second pixel.

Although not described, the same applies to the third light-emitting element, the third charge transport layer, the third metal oxide nanoparticle, the third organic ligand, the third charge transport layer material dispersion, the third photoresist layer, and the third pixel.

As described above, the method for manufacturing a light-emitting device according to the present embodiment includes, in manufacturing a light-emitting device including a first light-emitting element including a first light-emitting layer and a first charge transport layer provided on the first light-emitting layer: a step of forming a first photoresist layer in a region other than a region where the first light-emitting layer is to be formed; a step of forming the first light-emitting layer on the first photoresist layer; a step of forming the first charge transport layer on the first light-emitting layer; and a step of patterning the first light-emitting layer and the first charge transport layer by removing the first photoresist layer to lift off the first light-emitting layer and the first charge transport layer on the first photoresist layer, in which in the step of forming the first charge transport layer, after applying a first charge transport layer material dispersion containing a first metal oxide nanoparticle, a first organic ligand chemically bonded to the first metal oxide nanoparticle via a surface hydroxyl group of the first metal oxide nanoparticle and including fluorine at a terminal group, and a solvent, and having a bond enthalpy at 298 K between bonding atoms at a bonding site between the first organic ligand and the surface hydroxyl group of 326.7 kJ/mol or more, the solvent may be removed to form the first charge transport layer.

According to the above method, a high definition pattern of the first light-emitting layer and the first charge transport layer can be formed by lift-off. In addition, damage to the first light-emitting layer can be reduced by the liquid-repellent action of fluorine.

Furthermore, according to the above method, as described above, the bond enthalpy at 298 K between bonding atoms at a bonding site between the first organic ligand and the surface hydroxyl group in the first charge transport layer material dispersion is 326.7 kJ/mol or more, and thus the bonding of the first organic ligand to the first metal oxide nanoparticle in the first charge transport layer is strong, the detachment of the first organic ligand due to energization can be suppressed, and a light-emitting device capable of suppressing a change in electrical characteristics due to continuous driving can be manufactured.

In a case where the light-emitting device further includes a second light-emitting element including a second light-emitting layer and a second charge transport layer provided on the second light-emitting layer, the method for manufacturing a light-emitting device includes, after the step of patterning the first charge transport layer: a step of forming a second photoresist layer in a region other than a region where the second light-emitting layer is to be formed; a step of forming the second light-emitting layer on the second photoresist layer; a step of forming the second charge transport layer on the second light-emitting layer; and a step of patterning the second light-emitting layer and the second charge transport layer by removing the second photoresist layer to lift off the second light-emitting layer and the second charge transport layer on the second photoresist layer, in which in the step of forming the second charge transport layer, after applying a second charge transport layer material dispersion containing a second metal oxide nanoparticle, a second organic ligand chemically bonded to the second metal oxide nanoparticle via a surface hydroxyl group of the second metal oxide nanoparticle and including fluorine at a terminal group, and a solvent, and having a bond enthalpy at 298 K between bonding atoms at a bonding site between the second organic ligand and the surface hydroxyl group of 326.7 kJ/mol or more, the solvent may be removed to form the second charge transport layer.

This can form the first charge transport layer and the second charge transport layer made of different materials in the first light-emitting element and the second light-emitting element.

According to the above method, the charge transport layer having a bond enthalpy at 298 K between bonding atoms at a bonding site between the second organic ligand and the surface hydroxyl group of 326.7 kJ/mol or more is formed as the second charge transport layer, whereby it is possible to form the second charge transport layer in which the bonding of the second organic ligand to the second metal oxide nanoparticle is strong, the detachment of the second organic ligand due to energization can be suppressed, and a change in electrical characteristics due to continuous driving can be suppressed.

### Modified Example

In the present embodiment, as described above, the case where the light-emitting device is a display device and the light-emitting device includes a plurality of light-emitting elements 1 has been described as an example. However, the light-emitting device according to the embodiment is not limited thereto and may be, for example, an illumination device, and only need include at least one light-emitting element 1.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A light-emitting element comprising:
a first electrode;
a second electrode;
a light-emitting layer provided between the first electrode and the second electrode; and
a charge transport layer provided between the first electrode and the light-emitting layer,
wherein the charge transport layer includes a metal oxide nanoparticle,
an organic ligand is chemically bonded to the metal oxide nanoparticle via a surface hydroxyl group of the metal oxide nanoparticle,
a bond enthalpy at 298 K between bonding atoms at a bonding site between the organic ligand and the surface hydroxyl group is 326.7 kJ/mol or more, and
the organic ligand includes a phosphonic acid.

2. The light-emitting element according to claim 1,
wherein the charge transport layer is an electron transport layer.

3. The light-emitting element according to claim 2,
wherein the metal oxide nanoparticle is ZnO or MgZnO.

4. The light-emitting element according to claim 1,
wherein the charge transport layer is a hole transport layer.

5. (canceled)

6. (canceled)

7. A light-emitting element comprising:
a first electrode;
a second electrode;
a light-emitting layer provided between the first electrode and the second electrode; and
a charge transport layer provided between the first electrode and the light-emitting layer,
wherein the charge transport layer includes a metal oxide nanoparticle,
an organic ligand is chemically bonded to the metal oxide nanoparticle via a surface hydroxyl group of the metal oxide nanoparticle,
a bond enthalpy at 298 K between bonding atoms at a bonding site between the organic ligand and the surface hydroxyl group is 326.7 kJ/mol or more,
and the organic ligand includes fluorine at a terminal group.

8. The light-emitting element according to claim 7,
wherein the organic ligand includes a fluoroalkyl group.

9. The light-emitting element according to claim 1-5,
wherein the organic ligand is at least one selected from the group consisting of
1H,1H,2H,2H-perfluoro-n-hexylphosphonic acid,
1H,1H,2H,2H-perfluoro-n-octylphosphonic acid, and
1H,1H,2H,2H-perfluoro-n-decylphosphonic acid.

10. The light-emitting element according to claim 7,
wherein the charge transport layer is provided adjacently to the light-emitting layer on the light-emitting layer.

11. The light-emitting element according to claim 1,
wherein the organic ligand includes a carbon chain having 6 or more and 10 or less carbon atoms in a main chain.

12. A light-emitting device comprising:
at least one of the light-emitting elements according to claim 1.

13. The light-emitting device, comprising:
a first light-emitting element and a second light-emitting element,
wherein the first light-emitting element and the second light-emitting element are light-emitting elements recited in claim 1,
they emit light of different colors from each other as the light-emitting elements,
wherein the charge transport layer of the first light-emitting element and the charge transport layer of the second light-emitting element include different materials from each other.

14. A method for manufacturing a light-emitting device, the light-emitting device including a first light-emitting element including a first light-emitting layer and a first charge transport layer provided on the first light-emitting layer, the method comprising:
performing first photoresist layer formation of forming a first photoresist layer in a region other than a region where the first light-emitting layer is to be formed;
performing first light-emitting layer formation of forming the first light-emitting layer on the first photoresist layer;
performing first charge transport layer formation of forming the first charge transport layer on the first light-emitting layer; and
performing first light-emitting layer and first charge transport layer patterning of patterning the first light-emitting layer and the first charge transport layer by removing the first photoresist layer to lift off the first light-emitting layer and the first charge transport layer on the first photoresist layer,
wherein in the first charge transport layer formation,
after applying a first charge transport layer material dispersion including a first metal oxide nanoparticle, a first organic ligand chemically bonded to the first metal oxide nanoparticle via a surface hydroxyl group of the first metal oxide nanoparticle and including fluorine at a terminal group, and a solvent, the first charge transport layer material dispersion having a bond enthalpy at 298 K between bonding atoms at a bonding site between the first organic ligand and the surface hydroxyl group of 326.7 kJ/mol or more, the solvent is removed to form the first charge transport layer.

15. The method for manufacturing a light-emitting device according to claim 14, the light-emitting device further including a second light-emitting element including a second light-emitting layer and a second charge transport layer provided on the second light-emitting layer, the method further comprising:
performing second photoresist layer formation of forming a second photoresist layer in a region other than a region where the second light-emitting layer is to be formed, after the first charge transport layer patterning;
performing second light-emitting layer formation of forming the second light-emitting layer on the second photoresist layer;
performing second charge transport layer formation of forming the second charge transport layer on the second light-emitting layer; and
performing second light-emitting layer and second charge transport layer patterning of patterning the second light-emitting layer and the second charge transport layer by removing the second photoresist layer to lift off the second light-emitting layer and the second charge transport layer on the second photoresist layer,
wherein in the second charge transport layer formation,
as the second charge transport layer, a charge transport layer including a second metal oxide nanoparticle and a second organic ligand chemically bonded to the second metal oxide nanoparticle via a surface hydroxyl group of the second metal oxide nanoparticle and including fluorine at a terminal group, and having a bond enthalpy at 298 K between bonding atoms at a bonding site between the second organic ligand and the surface hydroxyl group of the second metal oxide nanoparticle of 326.7 kJ/mol or more is formed.
